(19) United States
(12) Patent Application Publication
(10) Pub. No.: US 2026/0223697 A1
(43) Pub. Date: Jul. 30, 2026

(54) COMPOSITE CIRCUIT LAMINATE AND MANUFACTURING METHOD THEREOF

(71) Applicants: Innolux Corporation, Miaoli County (TW); nD-HI Technologies Lab, Inc., Taipei City (TW)

(72) Inventors: Ching-Yu Chu, Miaoli County (TW); Chih-Chao Chuang, Miaoli County (TW); Shu-Fen Ku, Miaoli County (TW); Szu-Yen Yu, Miaoli County (TW); Ho-Ming Tong, Taipei City (TW)

(73) Assignees: Innolux Corporation, Miaoli County (TW); nD-HI Technologies Lab, Inc., Taipei City (TW)

(21) Appl. No.: 19/426,087

(22) Filed: Dec. 19, 2025

Related U.S. Application Data
(60) Provisional application No. 63/748,980, filed on Jan. 24, 2025.

(30) Foreign Application Priority Data
Aug. 21, 2025 (CN) 202511178056.0

(51) Int. Cl. H10W 70/60; H10W 70/05; H10W 70/63; H10W 70/685; H10W 90/22; H10W 90/00

(52) U.S. Cl. CPC H10W 70/614; H10W 70/093; H10W 70/095; H10W 70/635; H10W 70/686; H10W 90/22; H10W 90/724; H10W 90/734

(57) ABSTRACT

A composite circuit laminate including a first redistribution layer, a second redistribution layer, and a core composite layer is provided. The second redistribution layer is disposed opposite to the first redistribution layer. The core composite layer is located between the first redistribution layer and the second redistribution layer. The core composite layer at least includes a first core sublayer, a second core sublayer, and a third core sublayer. The first core sublayer, the second core sublayer, and the third core sublayer have unequal physical properties. A manufacturing method of the composite circuit laminate is also provided.

### CROSS-REFERENCE TO RELATED APPLICATION

This application claims the priority benefit of U.S. provisional application serial no. 63/748,980, filed on January 24, 2025, and China application serial no. 202511178056.0, filed on August 21, 2025. The entirety of each of the above-mentioned patent applications is hereby incorporated by reference herein and made a part of this specification.

### BACKGROUND

### Technical Field

The disclosure relates to a package structure and a manufacturing method thereof, and more particularly to a composite circuit laminate and a manufacturing method thereof.

### Description of Related Art

During a manufacturing process of an electronic device, a core layer (for example, a fiberglass material) in a conventional package carrier may easily cause the formed electronic device to warp, resulting in relatively poor reliability. For example, because the conductive layer and the core layer among the components for forming the electronic device have different physical properties (for example, coefficients of thermal expansion), the possibility of warpage increases after undergoing a process requiring relatively high temperatures, which may cause abnormal signal transmission in the formed electronic device, reducing the reliability of the electronic device.

### SUMMARY

The disclosure provides a composite circuit laminate, which can improve reliability.

In some embodiments of the disclosure, a composite circuit laminate includes a first redistribution layer, a second redistribution layer, and a core composite layer. The second redistribution layer is disposed opposite to the first redistribution layer. The core composite layer is located between the first redistribution layer and the second redistribution layer. The core composite layer at least includes a first core sublayer, a second core sublayer, and a third core sublayer. The first core sublayer, the second core sublayer, and the third core sublayer have unequal physical properties.

### BRIEF DESCRIPTION OF THE DRAWINGS

FIG. 1 is a schematic flowchart of a manufacturing method of a composite circuit laminate according to a first embodiment of the disclosure.

FIG. 2 is a schematic flowchart of a manufacturing method of a composite circuit laminate according to a second embodiment of the disclosure.

FIG. 3 is a schematic flowchart of a manufacturing method of a composite circuit laminate according to a third embodiment of the disclosure.

FIG. 4 is a schematic flowchart of a manufacturing method of a composite circuit laminate according to a fourth embodiment of the disclosure.

FIG. 5 is a schematic flowchart of a manufacturing method of a composite circuit laminate according to a fifth embodiment of the disclosure.

FIG. 6 is a schematic flowchart of a manufacturing method of a composite circuit laminate according to a sixth embodiment of the disclosure.

FIG. 7 is a schematic flowchart of a manufacturing method of a composite circuit laminate according to a seventh embodiment of the disclosure.

FIG. 8 is a schematic flowchart of a manufacturing method of a composite circuit laminate according to an eighth embodiment of the disclosure.

FIG. 9 is a partial cross-sectional schematic diagram of an electronic device according to an embodiment of the disclosure.

### DESCRIPTION OF THE EMBODIMENTS

Reference will now be made in detail to the exemplary embodiments of the disclosure, examples of the exemplary embodiments are illustrated in the drawings. Wherever possible, the same reference numerals are used in the drawings and the description to refer to the same or similar parts.

The disclosure may be understood by referring to the following detailed description in conjunction with the drawings. It should be noted that in order to facilitate the understanding of the reader and the brevity of the drawings, multiple drawings in the disclosure only depict a part of a composite circuit, and specific elements in the drawings are not drawn according to actual scale. In addition, the number and the size of each element in the drawings are for illustration only and are not intended to limit the scope of the disclosure.

Throughout the specification and the appended claims of the disclosure, certain terms may be used to refer to specific elements. It should be understood by persons skilled in the art that electronic device manufacturers may refer to the same element by different names. The disclosure does not intend to distinguish between elements with the same function but different names. In the following specification and claims, terms such as "including", "containing", and "having" are open-ended terms, so the terms should be interpreted as "containing but not limited to...". Therefore, when the terms " including", "containing", and/or "having" are used in the description of the disclosure, the terms designate the presence of a corresponding feature, region, step, operation, and/or component, but do not exclude the presence of one or more corresponding features, regions, steps, operations, and/or components.

Directional terms such as "upper", "lower", "front", "rear", "left", and "right" mentioned in the disclosure are only directions with reference to the drawings. Therefore, the used directional terms are used to illustrate, but not to limit, the disclosure. In the drawings, each drawing illustrates the general features of a method, a structure, and/or a material used in a specific embodiment. However, the drawings should not be construed to define or limit the scope or the nature covered by the embodiments. For example, for clarity, relative sizes, thicknesses, and positions of various film layers, regions, and/or structures may be reduced or enlarged.

When a corresponding component (for example, a film layer or a region) is referred to as being "on another component", the component may be directly on the other component or there may be another component between the two. On the other hand, when a component is referred to as being "directly on another component", there is no component between the two. In addition, when a component is referred to as being "on another component", the two have an upper-lower relationship in the top view direction, and the component may be above or below the other component, and the upper-lower relationship depends on the orientation of the device.

The terms "equal" or "same", "substantially", or "roughly" are generally interpreted as within 20% of a given value or range or interpreted as within 10%, 5%, 3%, 2%, 1%, or 0.5% of the given value or range.

Ordinal numbers such as "first" and "second" used in the specification and the claims are used to modify elements, and the terms do not imply and represent that the element(s) have any previous ordinal numbers, nor do they represent the order of a certain element and another element or the order of a manufacturing method. The use of the ordinal numbers is only to clearly distinguish between an element with a certain name and another element with the same name. The claims and the specification may not use the same terms, whereby a first component in the specification may be a second component in the claims.

It should be noted that in the following embodiments, features in several different embodiments may be replaced, recombined, and mixed to complete other embodiments without departing from the spirit of the disclosure. As long as the features of the various embodiments do not violate the spirit of the invention or conflict with each other, the features may be arbitrarily mixed and matched for use.

Electrical connection or coupling described in the disclosure may refer to both direct connection or indirect connection. In the case of direct connection, terminals of elements on two circuits are directly connected or connected to each other by a conductor segment. In the case of indirect connection, there is a switch, a diode, a capacitor, an inductor, a bridge element, other suitable elements, or a combination of the above elements between the terminals of the elements on the two circuits, but not limited thereto.

In the disclosure, the measurement manner of thickness, length, width, and area may be by adopting an optical microscope, and the thickness may be obtained by measuring a cross-sectional image in an electron microscope, but not limited thereto. In addition, there may be a certain error in any two values or directions for comparison. If a first value is equal to a second value, it implies that there may be an error of about 10% between the first value and the second value. If a first direction is perpendicular to a second direction, an angle between the first direction and the second direction may be between 80 degrees and 100 degrees; and if the first direction is parallel to the second direction, the angle between the first direction and the second direction may be between 0 degrees and 10 degrees. In addition, the phrases “a given range is from a first value to a second value” and “a given range falls within a range from a first value to a second value” mean that the given range includes the first value, the second value, and other values therebetween.

In the disclosure, the term “an element surrounding another element” may mean that in a cross-sectional diagram, the element contacts at least one surface of the other element.

It should be understood that according to the embodiments of the disclosure, an optical microscope (OM), a scanning electron microscope (SEM), an α-step, an ellipsometer, or other suitable manners may be used to measure the depth, the thickness, the width, or the height of each element or the spacing or the distance between elements. According to some embodiments, the scanning electron microscope may be used to obtain a cross-sectional structural image including an element to be measured, and the depth, the thickness, the width, or the height of each element or the spacing or the distance between the elements is measured.

A manufacturing process of an electronic device of the disclosure may be provided, for example, through a wafer-level package (WLP) process or a panel-level package (PLP) process, which may be a chip first process or a chip last process.

The electronic device of the disclosure may be applied to a high-speed computing module, a power module, a semiconductor package device, a display device, a light emitting device, a backlight device, an antenna device, a sensing device, or a splicing device, but not limited thereto. The electronic device includes a rollable, bendable, or flexible electronic device, but not limited thereto. The display device may be a non-self-luminous display device or a self-luminous display device. The electronic device may, for example, include a diode, liquid crystal, a light emitting diode (LED), quantum dot (QD), fluorescence, phosphor, other suitable display media, or a combination thereof. The antenna device may be a liquid crystal antenna device or a non-liquid crystal antenna device, and the sensing device may be a sensing device for sensing capacitance, light, heat energy, or ultrasonic waves, but not limited thereto. The light emitting diode may include, for example, an organic light emitting diode (OLED), a micro LED, a mini LED, or a quantum dot LED (QLED or QDLED), but not limited thereto. The splicing device may, for example, be a display splicing device or an antenna splicing device, but not limited thereto. It should be noted that the electronic device may be any permutation and combination of the above, but not limited thereto. In addition, the appearance of the electronic device may be a rectangle, a circle, a polygon, a shape with curved edges, or other suitable shapes. The electronic device may have a peripheral system such as a driving system, a control system, and a light source system to support the display device, the antenna device, a wearable device (such as including augmented reality or virtual reality), a vehicle-mounted device (such as including a car windshield), or the splicing device. The electronic device may include an electronic element, wherein the electronic element may include a passive element and an active element, such as a capacitor, a resistor, an inductor, a diode, a transistor, and a sensor. It should be noted that the electronic device of the disclosure may be various combinations of the above devices, but not limited thereto. A manufacturing method of a package device of the disclosure may be, for example, applied to the wafer-level package (WLP) process or the panel-level package (PLP) process, wherein the wafer-level package or panel-level package process may include the chip first process or the chip last process, but not limited thereto. The electronic device may include a package device such as high bandwidth memory (HBM) package, system on chip (SoC), system in package (SiP), antenna in package (AiP), co-packaged optics (CPO), or various combinations of the above devices, but not limited thereto.

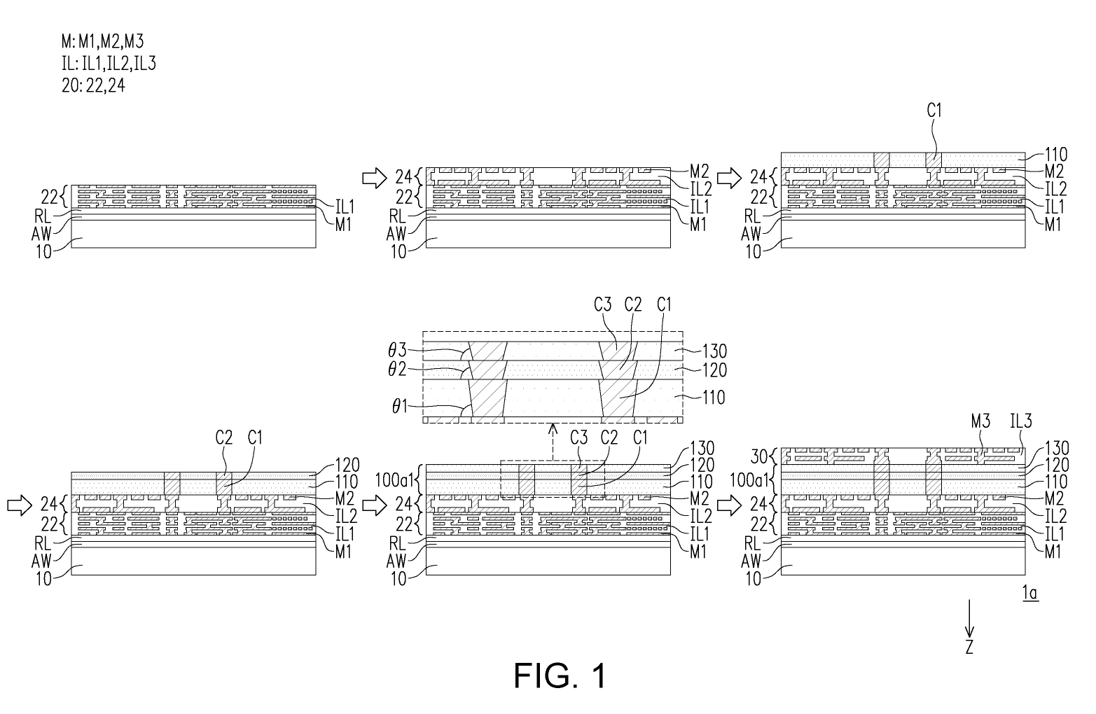

FIG. 1 is a schematic flowchart of a manufacturing method of a composite circuit laminate according to a first embodiment of the disclosure.

Please refer to FIG. 1. In some embodiments, a composite circuit laminate 1a may be formed through performing the following steps, but the disclosure is not limited thereto.

Step (1) is performed to provide a carrier 10.

The material of the carrier 10 may have, for example, certain stiffness and insulation properties. In other words, the rigidity of the carrier 10 may be greater than the rigidity of a redistribution layer or a build-up structure formed thereon, so that the possibility of warpage of the carrier 10 when used to carry the redistribution layer or the build-up structure may be reduced, but the disclosure is not limited thereto. It is worth noting that the “rigidity” referred to in the disclosure may be tested by a universal testing machine (UTM). The material of the carrier 10 may include, for example, a transparent material. For example, the material of the carrier 10 may be glass, alkali-free glass, quartz glass, or other suitable materials. In the embodiment, the carrier 10 is a glass carrier, but the disclosure is not limited thereto.

Step (2) is performed to form a redistribution layer 20 on the carrier 10

The redistribution layer 20 may be formed, for example, through alternately forming multiple insulating layers IL and multiple conductive layers M on the carrier 10. In some embodiments, the redistribution layer 20 is used to redistribute circuits and/or further increase circuit fan-out area. In addition, different electronic elements may be electrically connected to each other through the formation of the redistribution layer 20. For example, the electronic elements to be described later may be electrically connected to each other through the redistribution layer 20 or the redistribution layer 20 may be a substrate used as electrical interface wiring between one connection and another connection. In other words, the purpose of the redistribution layer 20 is to expand a connection to a wider spacing or to reallocate a connection to another connection with a different spacing. In some embodiments, the insulating layers IL and the conductive layers M may be each formed through performing a suitable deposition process and patterning process. In the embodiment, the redistribution layer 20 includes a redistribution layer 22 and a redistribution layer 24 stacked on the carrier 10, but the disclosure is not limited thereto.

The redistribution layer 22, for example, includes multiple insulating layers IL1 and multiple conductive layers M1 that are alternately stacked, and the redistribution layer 24, for example, includes multiple insulating layers IL2 and multiple conductive layers M2 that are alternately stacked. In some embodiments, the materials of the insulating layers IL1 and the insulating layers IL2 may include photosensitive polyimide (PSPI), Ajinomoto build-up film (ABF), polyimide (PI), polybenzoxazole (PBO), epoxy, polymer, isoaniline, silicon oxide (SiOₓ), silicon nitride (SiNₓ), other suitable insulating materials, or a combination thereof. In the embodiment, the material of the insulating layers IL1 may be selected from photosensitive polyimide, silicon oxide, silicon nitride, or a combination thereof, and the material of the insulating layers IL2 may be selected from photosensitive polyimide, Ajinomoto build-up film, or a combination thereof, but the disclosure is not limited thereto. In some other embodiments, the material of the insulating layers IL1 may be the same as or similar to the material of the insulating layers IL2. In some embodiments, the materials of the conductive layers M1 and the conductive layers M2 may include copper (Cu), aluminum (Al), molybdenum (Mo), tungsten (W), gold (Au), chromium (Cr), nickel (Ni), platinum (Pt), titanium (Ti), silver (Ag), tantalum (Ta), metal nitride, other suitable conductive materials, or a combination thereof, but the disclosure is not limited thereto. In the embodiment, the conductive layers M1 in the redistribution layer 22 is electrically connected to the conductive layers M2 in the redistribution layer 24.

In some embodiments, after forming the insulating layers IL and the conductive layers M, a surface modification process may be performed, so that surfaces of the insulating layers IL and/or surfaces of the conductive layers M form rough surfaces, wherein the surface roughness of the insulating layers IL may be greater than the surface roughness of the substrate 10.

It is worth noting that in the embodiment, before forming the redistribution layer 20 on the carrier 10, a release layer RL and an anti-warping layer AW are formed on the carrier 10.

The release layer RL is formed, for example, between the carrier 10 and the redistribution layer 20. The material of the release layer RL may include a matrix selected from organic resin, oxide, or a polymer composite material and may include a decomposition agent selected from a heat-sensitive compound, a photoreactive compound, redox-active salt, or moisture-sensitive compound. In addition, a selective energy absorption additive may also be included, but not limited thereto. The selected material of the release layer RL may decompose or release gas under stimulation such as heat, light, electric field, or chemical exposure, so as to separate upper and lower layers attached thereto. Therefore, the provision of the release layer RL enables components subsequently formed on the carrier 10 to be easily separated therefrom.

The anti-warping layer AW is, for example, formed between the carrier 10 and the release layer RL. In some embodiments, the material of the anti-warping layer AW may include an inorganic material (for example, silicon oxide, silicon nitride, silicon oxynitride, or a stacked layer of at least two of the above materials), an organic material (for example, polyimide resin, epoxy, or acrylic resin), or a combination thereof, but the disclosure is not limited thereto. The anti-warping layer AW may have, for example, a single-layer structure or a multi-layer structure, but the disclosure is not limited thereto. In some embodiments, the anti-warping layer AW may be made of a material with a suitable coefficient of thermal expansion to reduce the possibility of warpage of other layers when subsequently formed on the carrier 10.

Step (3A) is performed to form a core composite layer 100a1 on the redistribution layer 20.

In some embodiments, the core composite layer 100a1 may be formed through performing the following steps, but the disclosure is not limited thereto.

Step (3A-1) is performed to form multiple conductive pillars C1 on the redistribution layer 20.

In some embodiments, the material of the conductive pillars C1 may include a suitable conductive material. In the embodiment, the material of the conductive pillars C1 is copper, but the disclosure is not limited thereto. The conductive pillars C1 may be, for example, disposed on a surface of the redistribution layer 24 away from the redistribution layer 22 and electrically connected to the conductive layers M2 in the redistribution layer 24.

Step (3A-2) is performed to form a core sublayer 110 on the redistribution layer 20, wherein the core sublayer 110 surrounds the conductive pillars C1.

In some embodiments, the material of the core sublayer 110 may include an inorganic material, an organic material, or a combination thereof. In addition, the core sublayer 110 may include, for example, multiple filling particles, but the disclosure is not limited thereto. In the embodiment, the core sublayer 110 exposes a surface of the conductive pillars C1 away from the redistribution layer 24. Specifically, after forming the core sublayer 110, a part of the core sublayer 110 located on the conductive pillars C1 may be removed, for example, through performing a grinding process to expose surfaces of the conductive pillars C.

Step (3A-3) is performed to form multiple conductive pillars C2 on the core sublayer 110.

In some embodiments, the material of the conductive pillars C2 may include a suitable conductive material. In the embodiment, the material of the conductive pillars C2 is copper, but the disclosure is not limited thereto. The conductive pillars C2 may be, for example, disposed on a surface of the core sublayer 110 away from the redistribution layer 24 and electrically connected to the conductive pillars C1. In other words, the conductive pillars C2 may partially overlap with the conductive pillars C1 in a direction Z.

Step (3A-4) is performed to form a core sublayer 120 on the core sublayer 110, wherein the core sublayer 120 surrounds the conductive pillars C2.

In some embodiments, the material of the core sublayer 120 may include an inorganic material, an organic material, or a combination thereof. In addition, the core sublayer 120 may include, for example, multiple filling particles, but the disclosure is not limited thereto. In the embodiment, the core sublayer 120 exposes surfaces of the conductive pillars C2 away from the core sublayer 110. Specifically, after forming the core sublayer 120, a part of the core sublayer 120 located on the surfaces of the conductive pillars C2 away from the core sublayer 110 may be removed, for example, through performing a grinding process.

In the embodiment, the physical properties of the core sublayer 120 are different from the physical properties of the core sublayer 110. Specifically, the core sublayer 120 and the core sublayer 110 may have different coefficients of thermal expansion (CTE), different Young’s moduli, and/or other different physical properties through adjusting material, thickness, particle size, and/or other features of the core sublayer 120 and the core sublayer 110.

Step (3A-5) is performed to form multiple conductive pillars C3 on the core sublayer 120.

In some embodiments, the material of the conductive pillars C3 may include a suitable conductive material. In the embodiment, the material of the conductive pillars C3 is copper, but the disclosure is not limited thereto. The conductive pillars C3 may be, for example, disposed on a surface of the core sublayer 120 away from the core sublayer 110 and electrically connected to the conductive pillars C2. In other words, the conductive pillars C3 may partially overlap with the conductive pillars C2 in the direction Z.

Step (3A-6) is performed to form a core sublayer 130 on the core sublayer 120, wherein the core sublayer 130 surrounds the conductive pillars C3.

In some embodiments, the material of the core sublayer 130 may include an inorganic material, an organic material, or a combination thereof. In addition, the core sublayer 130 may include, for example, multiple filling particles, but the disclosure is not limited thereto. In the embodiment, the core sublayer 130 exposes surfaces of the conductive pillars C3 away from the core sublayer 120. Specifically, after forming the core sublayer 130, a part of the core sublayer 130 located on the surfaces of the conductive pillars C3 away from the core sublayer 120 may be removed, for example, through performing a grinding process.

In the embodiment, the physical properties of the core sublayer 130 are different from the physical properties of the core sublayer 120. Specifically, the core sublayer 130 and the core sublayer 120 may have different coefficients of thermal expansion, Young’s moduli, and/or other physical properties through adjusting material, thickness, particle size, and/or other features of the core sublayer 130 and the core sublayer 120.

Additionally, in some embodiments, the physical properties of the core sublayer 130 may be different from the physical properties of the core sublayer 110, but the disclosure is not limited thereto.

At this point, the process of forming the core composite layer 100a1 on the redistribution layer 20 is completed, but the disclosure is not limited to the above steps.

In the embodiment, an included angle θ1 may be formed between a side surface of the conductive pillar C1 and a top surface of the redistribution layer 20, and the included angle θ1 is less than 90 degrees. Similarly, an included angle θ2 may be formed between a side surface of the conductive pillar C2 and a top surface of the conductive pillar C1, and the included angle θ2 may be less than 90 degrees. An included angle θ3 may be formed between a side surface of the conductive pillar C3 and a top surface of the conductive pillar C2, and the included angle θ3 may be less than 90 degrees. In detail, the conductive pillar C1, the conductive pillar C2, or the conductive pillar C3 has an inverted trapezoidal shape in the cross-sectional diagram of the composite circuit laminate 1a of FIG. 1, and two sides thereof respectively have a slope greater than 0.

Step (4) is performed to form a redistribution layer 30 on the core composite layer 100a1.

The redistribution layer 30 may be formed, for example, through alternately forming multiple insulating layers IL3 and multiple conductive layers M3 on the core composite layer 100a1, wherein the material of the insulating layers IL3 includes the above materials of the insulating layers IL1 and the insulating layers IL2. In the embodiment, the material of the insulating layers IL3 may be selected from photosensitive polyimide, Ajinomoto build-up film, or a combination thereof. Reference may be made to the above embodiment about the redistribution layer 20 for the remaining description about the redistribution layer 30, which will not be repeated here.

It is worth noting that after performing step (4), the carrier 10 may be removed, but the disclosure is not limited thereto.

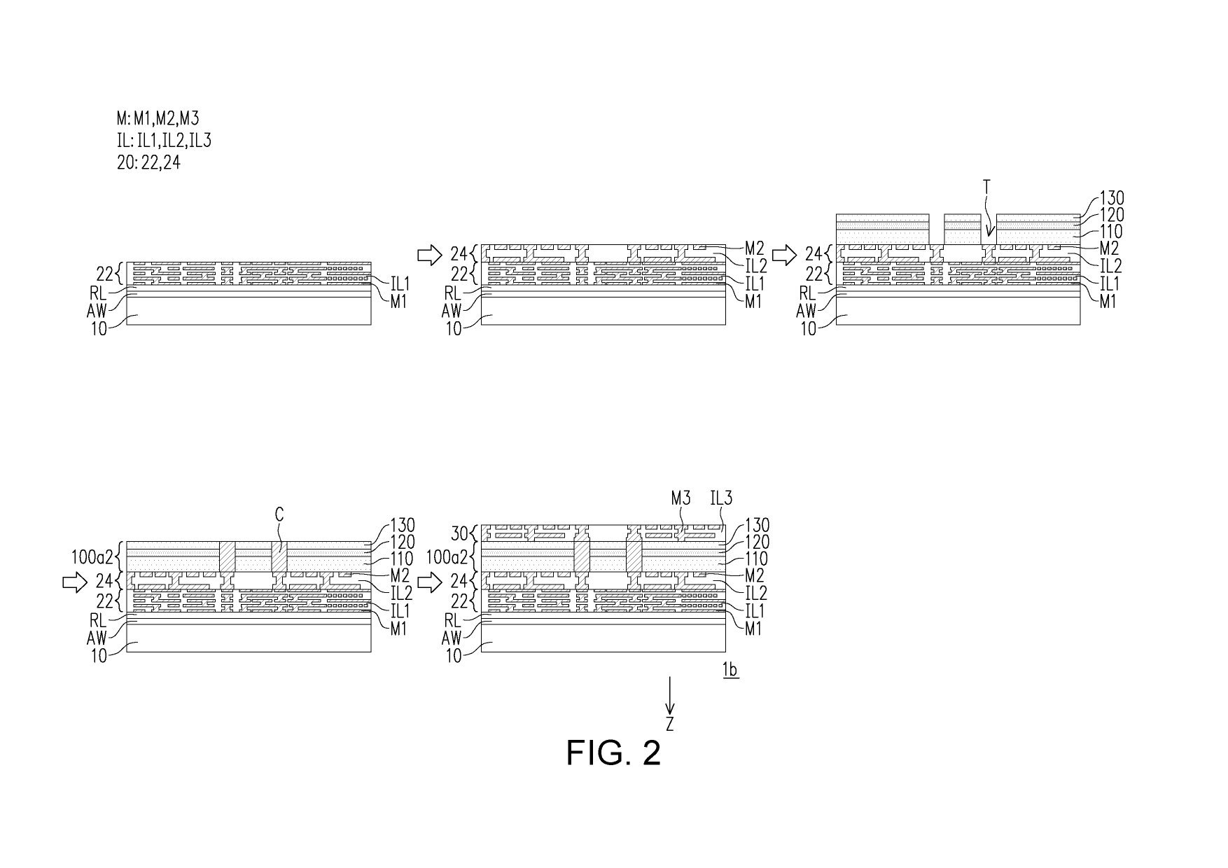

FIG. 2 is a schematic flowchart of a manufacturing method of a composite circuit laminate according to a second embodiment of the disclosure. It should be noted that the embodiment of FIG. 2 may continue to use the reference numerals and some contents of the embodiment of FIG. 1, wherein the same or similar numerals are adopted to represent the same or similar elements, and the description of the same technical content is omitted.

In the embodiment, a manufacturing method of a composite circuit laminate 1b differs from the manufacturing method of the composite circuit laminate 1a of the above embodiment in that after performing step (1) and step (2), step (3B) is performed.

Please refer to FIG. 2. Step (3B) is performed to form a core composite layer 100a2 on the redistribution layer 20.

In some embodiments, the core composite layer 100a2 may be formed through performing the following steps, but the disclosure is not limited thereto.

Step (3B-1) is performed to sequentially form the core sublayer 110, the core sublayer 120, and the core sublayer 130 on the redistribution layer 20.

In some embodiments, the core sublayer 110, the core sublayer 120, and the core sublayer 130 may be stacked on each other on the redistribution layer 20, and the core sublayer 110, the core sublayer 120, and the core sublayer 130 may have different physical properties.

Step (3B-2) is performed to form a through hole T penetrating the core sublayer 110, the core sublayer 120, and the core sublayer 130.

In some embodiments, multiple through holes T may be formed through performing an etching process and a drilling process. For example, the through holes T may be formed in the core sublayer 110, the core sublayer 120, and the core sublayer 130a through performing a laser drilling process, but the disclosure is not limited thereto. In the embodiment, at least one of the through holes T exposes a part of the conductive layers M2 in the redistribution layer 24.

Step (3B-3) is performed to form multiple conductive pillars C in the corresponding through holes T.

In some embodiments, the material of the conductive pillars C may include a suitable conductive material. In the embodiment, the material of the conductive pillars C is copper, but the disclosure is not limited thereto. In the embodiment, the conductive pillars C may be electrically connected to the conductive layers M2 in the redistribution layer 24 through the corresponding through holes T.

In some embodiments, after forming the conductive pillars C, a part of the conductive pillars C on a surface of the core sublayer 130 may be removed, for example, through performing a grinding process to expose a top surface of the core sublayer 130.

At this point, the process of forming the core composite layer 100a2 on the redistribution layer 20 is completed, but the disclosure is not limited to the above steps.

After performing the process of forming the core composite layer 100a2 on the redistribution layer 20, step (4) may be performed, which will not be repeated here. It is worth noting that after performing step (4), the carrier 10 may be removed, but the disclosure is not limited thereto.

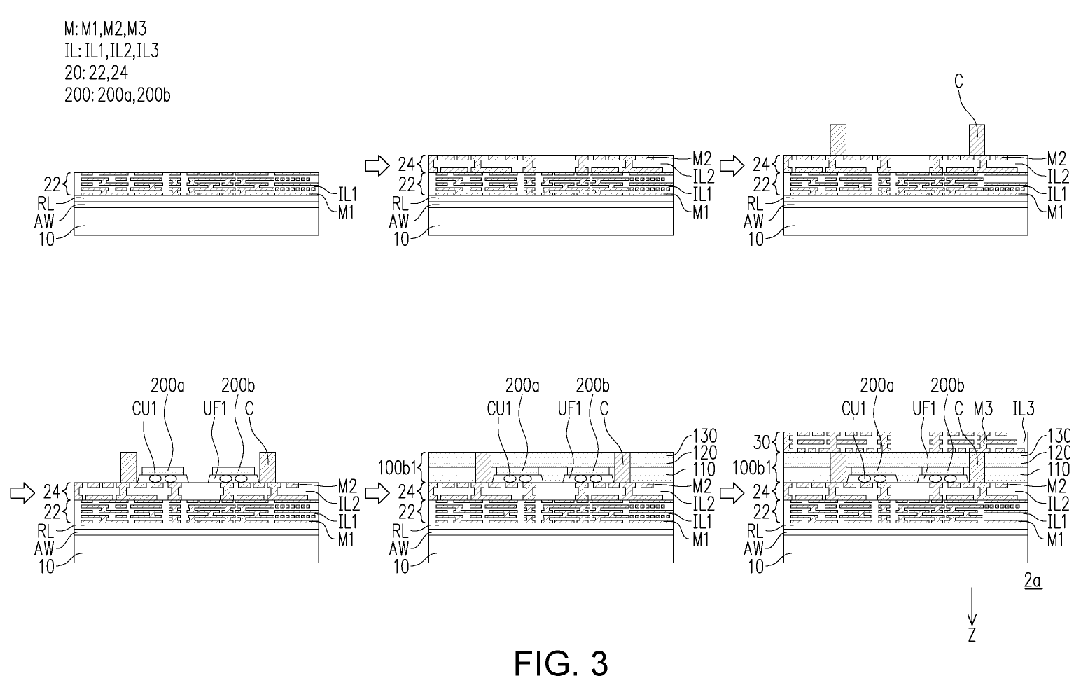

FIG. 3 is a schematic flowchart of a manufacturing method of a composite circuit laminate according to a third embodiment of the disclosure. It should be noted that the embodiment of FIG. 3 may continue to use the reference numerals and some contents of the embodiment of FIG. 1, wherein the same or similar numerals are adopted to represent the same or similar elements, and the description of the same technical content is omitted.

In the embodiment, a manufacturing method of a composite circuit laminate 2a differs from the manufacturing method of the composite circuit laminate 1a in the above embodiment in that after performing step (1) and step (2), step (3C) is performed.

Please refer to FIG. 3. Step (3C) is performed to form a core composite layer 100b1 on the redistribution layer 20.

In some embodiments, the core composite layer 100b1 may be formed through performing the following steps, but the disclosure is not limited thereto.

Step (3C-1) is performed to form the conductive pillars C on the redistribution layer 20.

In some embodiments, the material of the conductive pillars C may include a suitable conductive material. In the embodiment, the material of the conductive pillars C is copper, but the disclosure is not limited thereto. In the embodiment, the conductive pillars C may be electrically connected to the conductive layers M2 in the redistribution layer 24.

Step (3C-2) is performed to form multiple chips 200 on the redistribution layer 20.

Each of the chips 200 may have the same function or different functions. In the embodiment, the chips 200 may be disposed between the adjacent conductive pillars C, but the disclosure is not limited thereto.

In some embodiments, the chips 200 includes two chips 200a and 200b. The chips 200aand 200b may be each electrically connected to the conductive layers M2 in the redistribution layer 24 through multiple connection units CU1. One of the chips 200 may include a passive element, an active element, an optical element, a bridge element, or other suitable electronic elements, but the disclosure is not limited thereto. In some embodiments, the material of the connection units CU1 may include tin, copper, nickel, silver, gold, gallium, or other suitable materials. For example, the connection units CU1 may be solder balls, but the disclosure is not limited thereto.

In the embodiment, an adhesive layer UF1 is formed on the redistribution layer 20. The adhesive layer UF1 is, for example, disposed between the chips 200 and the redistribution layer 20. In detail, the adhesive layer UF1 may directly contact active surfaces of the chips 200 and fill spaces between the two adjacent connection units CU1. The material of the adhesive layer UF1 may include a suitable inorganic material or organic material, but the disclosure is not limited thereto. In some embodiments, the adhesive layer UF1 may include an adhesive for fixing the chips 200.

Step (3C-3) is performed to sequentially form the core sublayer 110, the core sublayer 120, and the core sublayer 130 on the redistribution layer 20.

In some embodiments, the core sublayer 110, the core sublayer 120, and the core sublayer 130 may be stacked on each other on the redistribution layer 20, and the core sublayer 110, the core sublayer 120, and the core sublayer 130 may have different physical properties. In the embodiment, the core sublayer 110, the core sublayer 120, and the core sublayer 130 may each surround corresponding side surfaces of the conductive pillars C and expose top surfaces of the conductive pillars C. It is worth noting that after forming the core sublayer 110, the core sublayer 120, and the core sublayer 130, a part of the core sublayer 130 located on the top surfaces of the conductive pillars C may be removed, for example, through performing a grinding process. In the embodiment, the core composite layer 100b1 embedded with the chips 200 may be formed and may be used to improve the signal transmission performance of the composite circuit laminate 2a.

At this point, the process of forming the core composite layer 100b1 on the redistribution layer 20 is completed, but the disclosure is not limited to the above steps.

After performing the process of forming the core composite layer 100b1 on the redistribution layer 20, step (4) may be performed, which will not be repeated here. It is worth noting that after performing step (4), the carrier 10 may be removed, but the disclosure is not limited thereto.

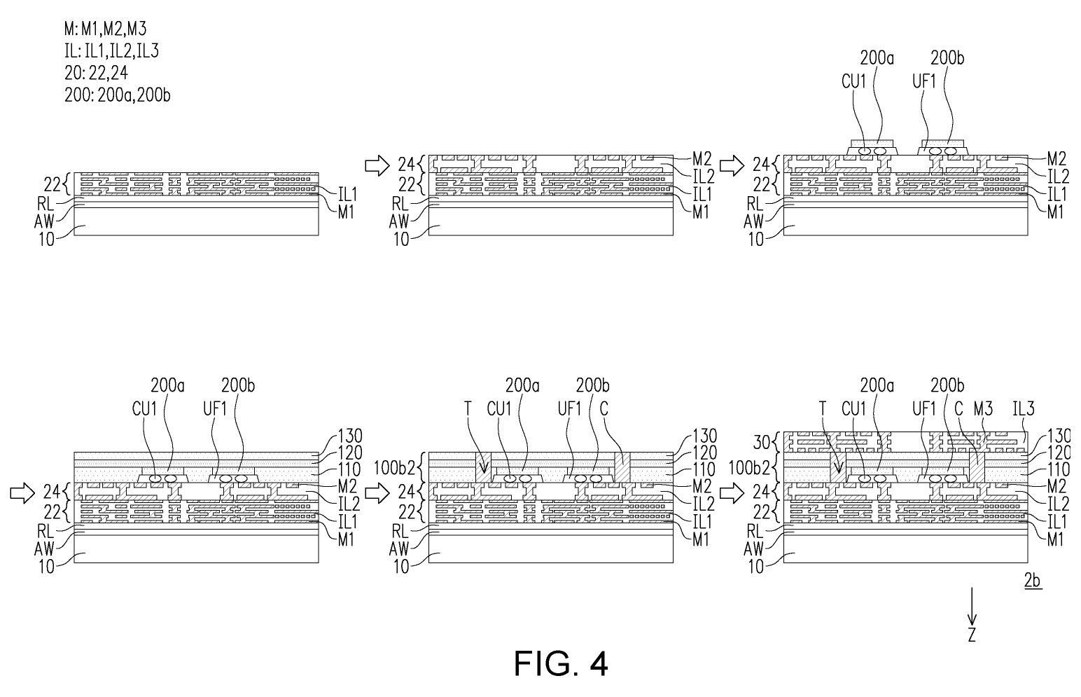

FIG. 4 is a schematic flowchart of a manufacturing method of a composite circuit laminate according to a fourth embodiment of the disclosure. It should be noted that the embodiment of FIG. 4 may continue to use the reference numerals and some contents of the embodiment of FIG. 3, wherein the same or similar numerals are adopted to represent the same or similar elements, and the description of the same technical content is omitted.

In the embodiment, a manufacturing method of a composite circuit laminate 2b differs from the manufacturing method of the composite circuit laminate 2a in the above embodiment in that after performing step (1) and step (2), step (3D) is performed.

Please refer to FIG. 4. Step (3D) is performed to form a core composite layer 100b2 on the redistribution layer 20.

In some embodiments, the core composite layer 100b2 may be formed through performing the following steps, but the disclosure is not limited thereto.

Step (3D-1) is performed to form the chips 200 on the redistribution layer 20.

The chips 200 may be each, for example, electrically connected to the conductive layers M2 in the redistribution layer 24 through the connection units CU1 and adhered to the redistribution layer 20 through the adhesive layer UF1.

Step (3D-2) is performed to sequentially form the core sublayer 110, the core sublayer 120, and the core sublayer 130 on the redistribution layer 20.

In the embodiment, the core sublayer 110, the core sublayer 120, and the core sublayer 130 may be stacked on each other on the redistribution layer 20 and may cover the chips 200.

Step (3D-3) is performed to form the through hole T penetrating the core sublayer 110, the core sublayer 120, and the core sublayer 130.

In the embodiment, at least one of the through holes T exposes a part of the conductive layers M2 in the redistribution layer 24.

Step (3D-4) is performed to form the conductive pillars C in the corresponding through holes T.

In the embodiment, the conductive pillars C may be electrically connected to the conductive layers M2 in the redistribution layer 24 through the corresponding through holes T.

At this point, the process of forming the core composite layer 100b2 on the redistribution layer 20 is completed, but the disclosure is not limited to the above steps.

After performing the process of forming the core composite layer 100b2 on the redistribution layer 20, step (4) may be performed, which will not be repeated here. It is worth noting that after performing step (4), the carrier 10 may be removed, but the disclosure is not limited thereto.

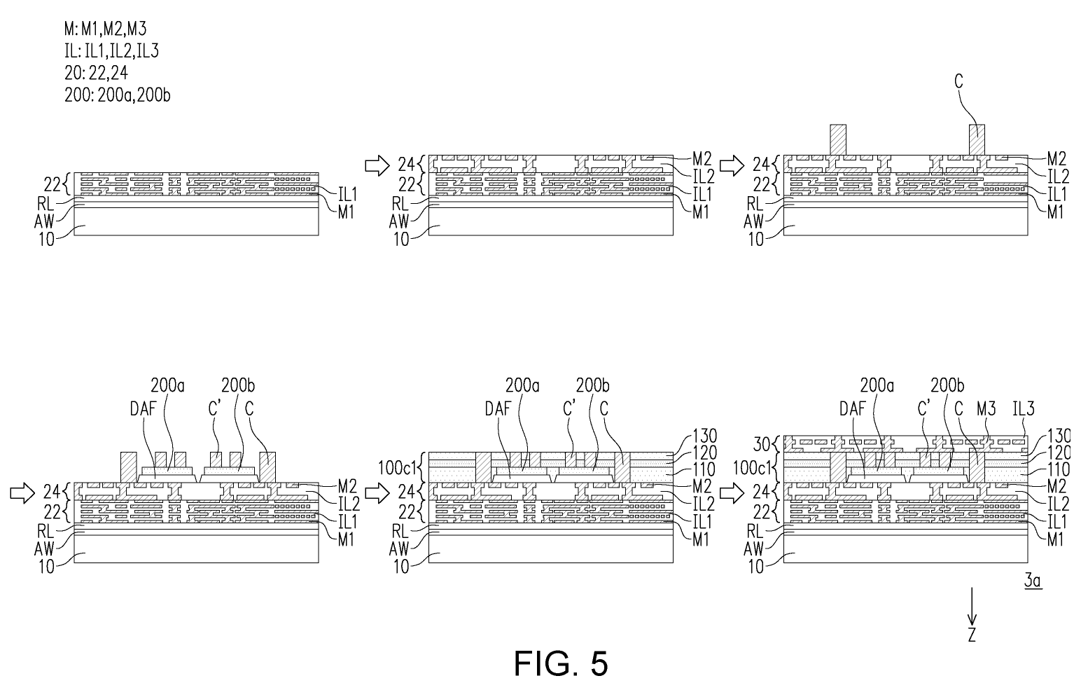

FIG. 5 is a schematic flowchart of a manufacturing method of a composite circuit laminate according to a fifth embodiment of the disclosure. It should be noted that the embodiment of FIG. 5 may continue to use the reference numerals and some contents of the embodiment of FIG. 3, wherein the same or similar numerals are adopted to represent the same or similar elements, and the description of the same technical content is omitted.

In the embodiment, a manufacturing method of a composite circuit laminate 3a differs from the manufacturing method of the composite circuit laminate 2a in the above embodiment in that after performing step (1) and step (2), step (3E) is performed.

Please refer to FIG. 5. Step (3E) is performed to form a core composite layer 100c1 on the redistribution layer 20.

In some embodiments, the core composite layer 100c1 may be formed through performing the following steps, but the disclosure is not limited thereto.

Step (3E-1) is performed to form the conductive pillars C on the redistribution layer 20.

In the embodiment, the conductive pillars C may be electrically connected to the conductive layers M2 in the redistribution layer 24.

Step (3E-2) is performed to form the chips 200 on the redistribution layer 20.

The chips 200 are, for example, disposed between the adjacent conductive pillars C. In the embodiment, the chips 200 are adhered onto the redistribution layer 24 through a die attach film DAF. In other words, the active surfaces of the chips 200 are away from the redistribution layer 24. In addition, multiple conductive pillars C’ are disposed on the active surfaces of the chips 200.

Step (3E-3) is performed to sequentially form the core sublayer 110, the core sublayer 120, and the core sublayer 130 on the redistribution layer 20.

In the embodiment, the core sublayer 110, the core sublayer 120, and the core sublayer 130 may be stacked on each other on the redistribution layer 20, and the core sublayer 130 may expose top surfaces of the conductive pillars C and the conductive pillars C’.

At this point, the process of forming the core composite layer 100c1 on the redistribution layer 20 is completed, but the disclosure is not limited to the above steps.

After performing the process of forming the core composite layer 100c1 on the redistribution layer 20, step (4) may be performed, which will not be repeated here.

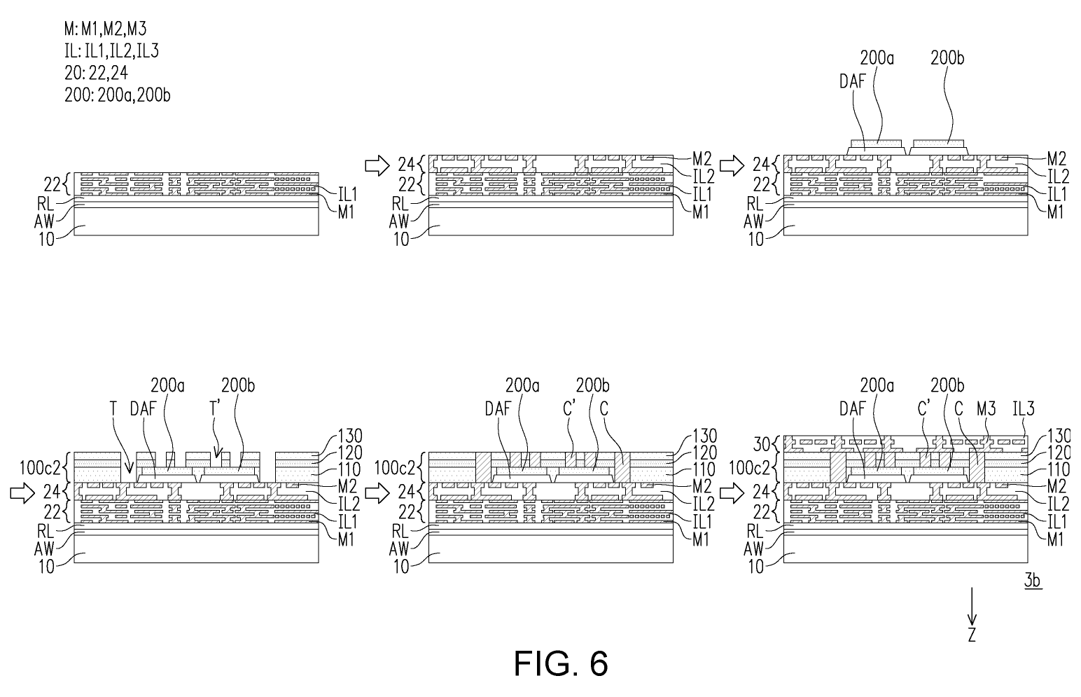

FIG. 6 is a schematic flowchart of a manufacturing method of a composite circuit laminate according to a sixth embodiment of the disclosure. It should be noted that the embodiment of FIG. 6 may continue to use the reference numerals and some contents of the embodiment of FIG. 5, wherein the same or similar numerals are adopted to represent the same or similar elements, and the description of the same technical content is omitted.

In the embodiment, a manufacturing method of a composite circuit laminate 3b differs from the manufacturing method of the composite circuit laminate 3a in the above embodiment in that after performing step (1) and step (2), step (3F) is performed.

Please refer to FIG. 6. Step (3F) is performed to form a core composite layer 100c2 on the redistribution layer 20.

In some embodiments, the core composite layer 100c2 may be formed through performing the following steps, but the disclosure is not limited thereto.

Step (3F-1) is performed to form the chips 200 on the redistribution layer 20.

In the embodiment, the chips 200 are adhered onto the redistribution layer 24 through the die attach film DAF.

Step (3F-2) is performed to sequentially form the core sublayer 110, the core sublayer 120, and the core sublayer 130 on the redistribution layer 20.

In the embodiment, the core sublayer 110, the core sublayer 120, and the core sublayer 130 may be stacked on each other on the redistribution layer 20 and may cover the chips 200.

Step (3F-3) is performed to form the through holes T penetrating the core sublayer 110, the core sublayer 120, and the core sublayer 130.

In the embodiment, at least one of the through holes T exposes a part of the conductive layers M2 in the redistribution layer 24.

In the embodiment, multiple through holes T’ penetrating the core sublayer 130 are formed, wherein at least one of the through holes T’ exposes the active surfaces of the chips 200.

Step (3F-4) is performed to form the conductive pillars C and the conductive pillars C’ in the corresponding through holes T and through holes T’.

In the embodiment, the conductive pillars C may be electrically connected to the conductive layers M2 in the redistribution layer 24 through the corresponding through holes T, and the conductive pillars C’ are electrically connected to the active surfaces of the chips 200.

At this point, the process of forming the core composite layer 100c2 on the redistribution layer 20 is completed, but the disclosure is not limited to the above steps.

After performing the process of forming the core composite layer 100c2 on the redistribution layer 20, step (4) may be performed, which will not be repeated here.

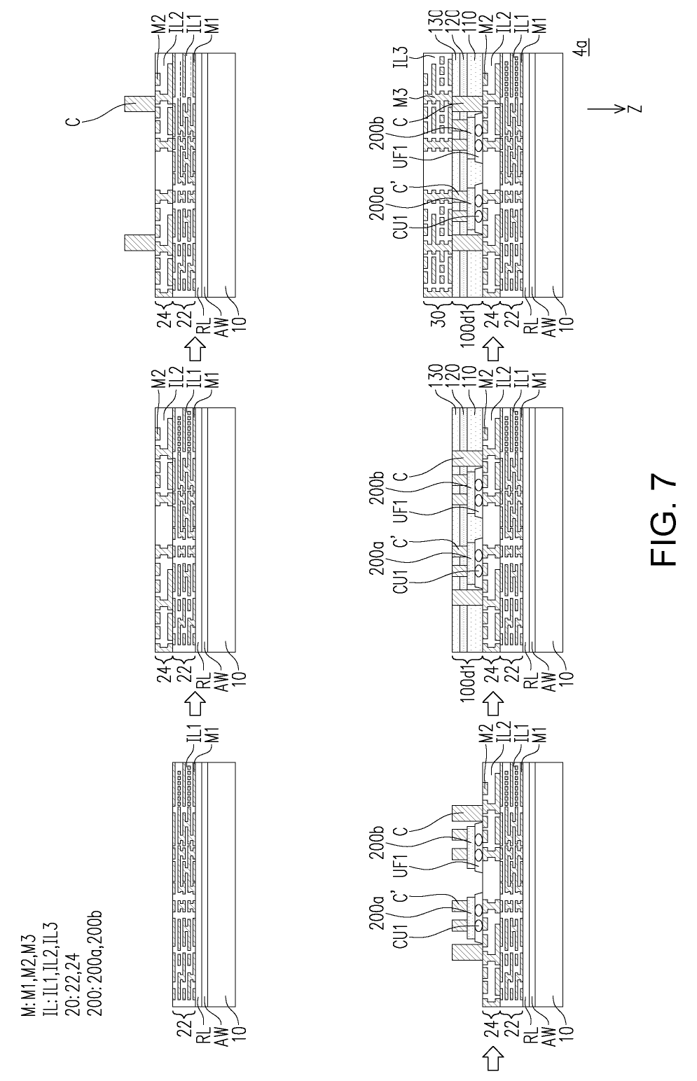

FIG. 7 is a schematic flowchart of a manufacturing method of a composite circuit laminate according to a seventh embodiment of the disclosure. It should be noted that the embodiment of FIG. 7 may continue to use the reference numerals and some contents of the embodiment of FIG. 3, wherein the same or similar numerals are adopted to represent the same or similar elements, and the description of the same technical content is omitted.

In the embodiment, a manufacturing method of a composite circuit laminate 4a differs from the manufacturing method of the composite circuit laminate 3a in the above embodiment in that after performing step (1) and step (2), step (3G) is performed.

Please refer to FIG. 7. Step (3G) is performed to form a core composite layer 100d1 on the redistribution layer 20.

In some embodiments, the core composite layer 100d1 may be formed through performing the following steps, but the disclosure is not limited thereto.

Step (3G-1) is performed to form the conductive pillars C on the redistribution layer 20.

In the embodiment, the conductive pillars C may be electrically connected to the conductive layers M2 in the redistribution layer 24.

Step (3G-2) is performed to form the chips 200 on the redistribution layer 20.

The chips 200 are, for example, disposed between the adjacent conductive pillars C. In the embodiment, the chips 200 are electrically connected to the conductive layers M2 in the redistribution layer 24 through the connection units CU1 and are adhered to the redistribution layer 20 through the adhesive layer UF1. In other words, the active surfaces of the chips 200 are close to the redistribution layer 24. In addition, the conductive pillars C’ are disposed on back surfaces of the chips 200 to improve heat dissipation efficiency or to electrically connect with a subsequently formed redistribution layer.

Step (3G-3) is performed to sequentially form the core sublayer 110, the core sublayer 120, and the core sublayer 130 on the redistribution layer 20.

In the embodiment, the core sublayer 110, the core sublayer 120, and the core sublayer 130 may be stacked on each other on the redistribution layer 20, and the core sublayer 130 may expose the top surfaces of the conductive pillars C and the conductive pillars C’.

At this point, the process of forming the core composite layer 100d1 on the redistribution layer 20 is completed, but the disclosure is not limited to the above steps.

After performing the process of forming the core composite layer 100d1 on the redistribution layer 20, step (4) may be performed, which will not be repeated here.

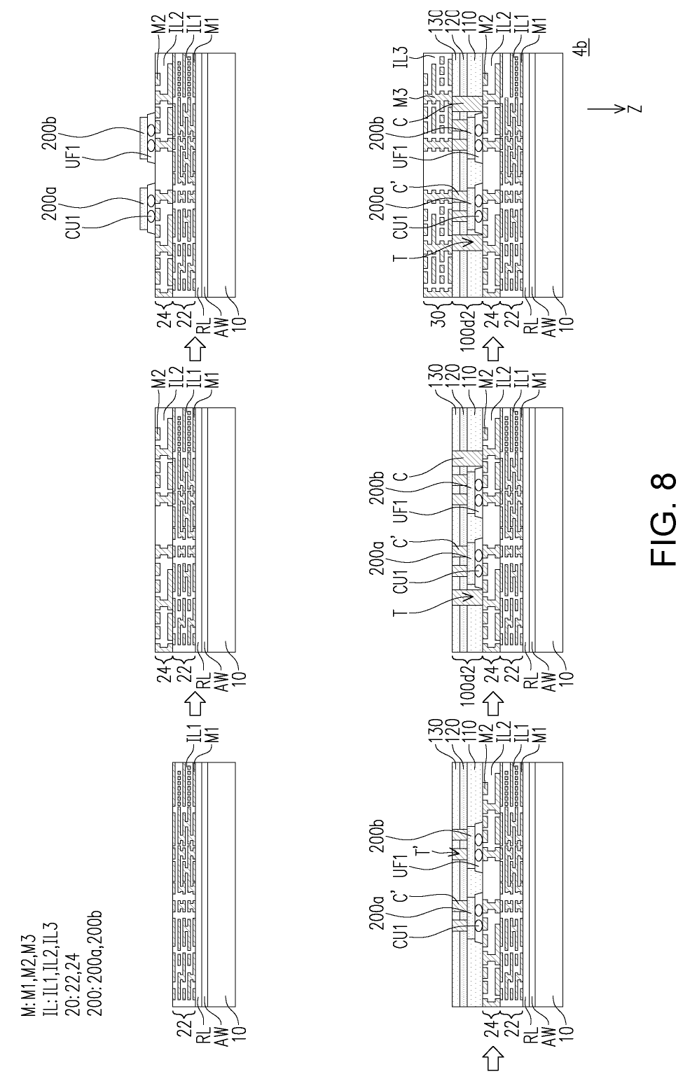

FIG. 8 is a schematic flowchart of a manufacturing method of a composite circuit laminate according to an eighth embodiment of the disclosure. It should be noted that the embodiment of FIG. 8 may continue to use the reference numerals and some contents of the embodiment of FIG. 7, wherein the same or similar numerals are adopted to represent the same or similar elements, and the description of the same technical content is omitted.

In the embodiment, a manufacturing method of a composite circuit laminate 4b differs from the manufacturing method of the composite circuit laminate 4a in the above embodiment in that after performing step (1) and step (2), step (3H) is performed.

Please refer to FIG. 8. Step (3H) is performed to form a core composite layer 100d2 on the redistribution layer 20.

In some embodiments, the core composite layer 100d2 may be formed through performing the following steps, but the disclosure is not limited thereto.

Step (3H-1) is performed to form the chips 200 on the redistribution layer 20.

In the embodiment, the chips 200 are electrically connected to the conductive layers M2 in the redistribution layer 24 through the connection units CU1 and are adhered to the redistribution layer 20 through the adhesive layer UF1.

Step (3H-2) is performed to sequentially form the core sublayer 110, the core sublayer 120, and the core sublayer 130 on the redistribution layer 20.

In the embodiment, the core sublayer 110, the core sublayer 120, and the core sublayer 130 may be stacked on each other on the redistribution layer 20 and may cover the chips 200.

Step (3H-3) is performed to form the through holes T penetrating the core sublayer 110, the core sublayer 120, and the core sublayer 130.

In the embodiment, at least one of the through holes T exposes a part of the conductive layers M2 in the redistribution layer 24. Reference may be made to the above embodiment for the remaining description about the through hole T, which will not be repeated here.

In the embodiment, the through holes T’ penetrating the core sublayer 120 and the core sublayer 130 are formed.

Step (3H-4) is performed to form the conductive pillars C in the corresponding through holes T and form the conductive pillars C’ in the corresponding through holes T’.

In the embodiment, the conductive pillars C may be electrically connected to the conductive layers M2 in the redistribution layer 24 through the corresponding through holes T, and the conductive pillars C’ are disposed on the back surfaces of the chips 200 to improve heat dissipation efficiency or to electrically connect with a subsequently formed redistribution layer.

At this point, the process of forming the core composite layer 100d2 on the redistribution layer 20 is completed, but the disclosure is not limited to the above steps.

After performing the process of forming the core composite layer 100d2 on the redistribution layer 20, step (4) may be performed, which will not be repeated here.

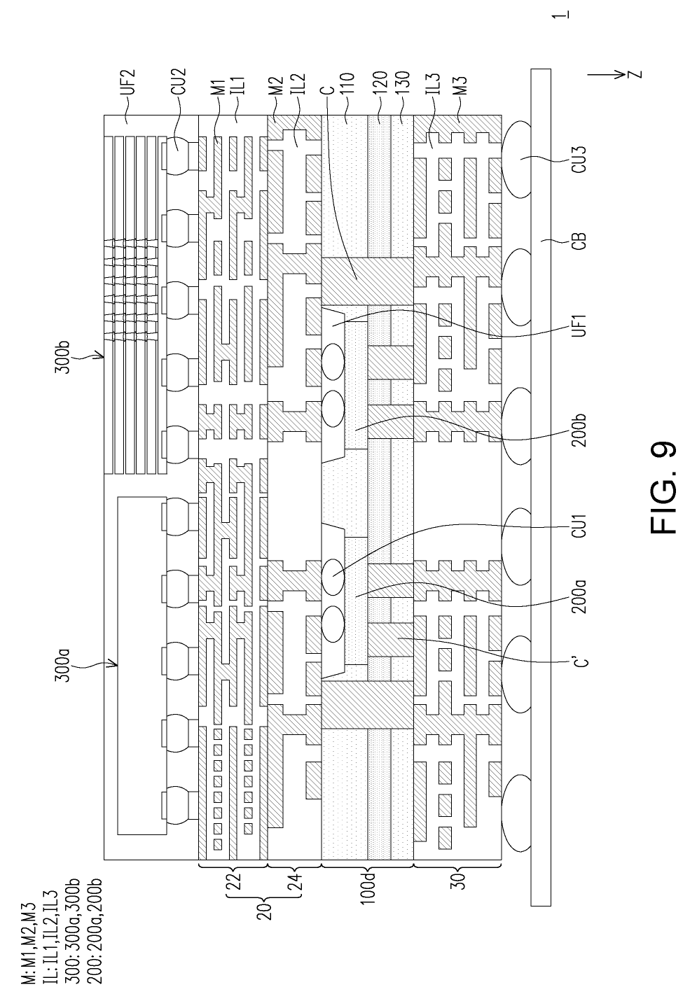

FIG. 9 is a partial cross-sectional schematic diagram of an electronic device according to an embodiment of the disclosure. It should be noted that the embodiment of FIG. 9 may continue to use the reference numerals and some contents of the above embodiments, wherein the same or similar numerals are adopted to represent the same or similar elements, and the description of the same technical content is omitted.

In the embodiment, an electronic device 1 may be formed through the manufacturing method of the composite circuit laminate 1a or 1b, the composite circuit laminate 2a or 2b, the composite circuit laminate 3a or 3b, or the composite circuit laminate 4a or 4b of the above embodiment, but the disclosure is not limited thereto.

Taking the composite circuit laminate 4a or 4b as an example, please refer to FIG. 9. In the embodiment, the electronic device 1 may include the redistribution layer 20, the redistribution layer 30, and a core composite layer 100d, wherein the at least one chip 200 is embedded in the core composite layer 100d.

The redistribution layer 20 is, for example, disposed opposite to the redistribution layer 30. In the embodiment, the redistribution layer 20 and the redistribution layer 30 are each located on opposite surfaces of the core composite layer 100d and may be electrically connected to each other through a conductive pillar C penetrating the core composite layer 100d.

The core composite layer 100d is, for example, located between the redistribution layer 20 and the redistribution layer 30. In some embodiments, the core composite layer 100d includes multiple structures stacked on each other, which may be, for example, the core composite layer 100d1 or the core composite layer 100d2, but the disclosure is not limited thereto. In the embodiment, the core composite layer 100d at least includes the core sublayer 110, the core sublayer 120, and the core sublayer 130 stacked on each other, but the disclosure is not limited thereto. The core sublayer 110, the core sublayer 120, and the core sublayer 130 have, for example, unequal physical properties. Specifically, the core sublayer 110, the core sublayer 120, and the core sublayer 130 may have different coefficients of thermal expansion, Young’s moduli, and/or other physical properties through adjusting material, thickness, particle size, and/or other features. In some embodiments, the particle sizes of the core sublayer 110, the core sublayer 120, and the core sublayer 130 may be less than 10 µm, between 10 µm and 50 µm, or greater than 50 µm.

Through the core sublayer 110, the core sublayer 120, and the core sublayer 130 having unequal physical properties, the possibility of warpage of the composite circuit laminate may be reduced. For example, when the core sublayer 110, the core sublayer 120, and the core sublayer 130 have different coefficients of thermal expansion, if a temperature change occurs, the tendency of the core composite layer 100d deforming toward a specific direction may be reduced, so as to reduce warpage of the composite circuit laminate.

In some embodiments, particles in the core sublayer 110, the core sublayer 120, and the core sublayer 130 may include heat dissipation particles to improve the heat dissipation performance of the electronic device 1.

In the embodiment, the electronic device 1 may further include multiple electronic elements 300 and a circuit board CB.

The electronic elements 300 may have the same function or different functions. In some embodiments, the electronic device 1 may be a 2.5D package structure in which the electronic elements 300 are horizontally placed side by side, but the disclosure is not limited thereto. In the embodiment, the electronic elements 300 are disposed on the redistribution layer 22 and may be electrically connected to the core composite layer 100d through the redistribution layer 22 and the redistribution layer 24.

In some embodiments, the electronic elements 300 includes two electronic elements 300a and 300b. The electronic elements 300a and 300b may be each electrically connected to the conductive layers M1 in the redistribution layer 22 through multiple connection units CU2. In some embodiments, the material of the connection units CU2 may include tin, copper, nickel, silver, gold, gallium, or other suitable materials. For example, the connection units CU2 may be solder balls, but the disclosure is not limited thereto. It is worth noting that the disclosure is not limited to the type of the electronic elements. In some embodiments, one of the electronic elements 300 may be a high bandwidth memory (HBM), a graphic processing unit (GPU), a dynamic random access memory (DRAM), a static random access memory (SRAM), a cache memory, a central processing unit (CPU), a digital signal processor (DSP), or an application specific integrated circuit (ASIC).

In the embodiment, the electronic device 1 may further include a package layer UF2. The package layer UF2, for example, surrounds and/or covers the electronic elements 300. In some embodiments, the material of the package layer UF 2 may include an epoxy molding compound (EMC), but the disclosure is not limited thereto.

The circuit board CB may be used, for example, to support the core composite layer 100d and the electronic elements 300. In some embodiments, the circuit board CB may be electrically connected to the core composite layer 100d through multiple connection units CU3 and the redistribution layer 30.

In summary, in the electronic device provided by some embodiments of the disclosure, through the core composite layer including multiple core sublayers having unequal physical properties, the possibility of warpage of the electronic device may be reduced, so as to improve the reliability of the electronic device. In addition, in the electronic device provided by other embodiments of the disclosure, the core sublayers may include heat dissipation particles, which may improve the heat dissipation performance of the electronic device. Furthermore, in the electronic device provided by some other embodiments of the disclosure, multiple chips may be embedded in the core composite layer, which may improve the signal transmission performance of the electronic device.

What is claimed is:

1. A composite circuit laminate, comprising:
a first redistribution layer;
a second redistribution layer, disposed opposite to the first redistribution layer; and
a core composite layer, located between the first redistribution layer and the second redistribution layer,
wherein the core composite layer at least comprises a first core sublayer, a second core sublayer, and a third core sublayer,
wherein the first core sublayer, the second core sublayer, and the third core sublayer have unequal physical properties.

2. The composite circuit laminate according to claim 1, wherein the physical property comprises a coefficient of thermal expansion, a Young’s modulus, or a particle size of the core composite layer.

3. The composite circuit laminate according to claim 2, wherein the particle sizes of the first core sublayer, the second core sublayer, and the third core sublayer are less than 10 µm, between 10 µm and 50 µm, or greater than 50 µm.

4. The composite circuit laminate according to claim 1, wherein the core composite layer comprises a plurality of chips, and the chips are selected from at least one of groups composed of a passive element, an active element, an optical element, and a bridge element.

5. The composite circuit laminate according to claim 4, wherein active surfaces of the chips are close to the first redistribution layer.

6. The composite circuit laminate according to claim 4, wherein active surfaces of the chips are away from the first redistribution layer.

7. The composite circuit laminate according to claim 5, wherein a plurality of conductive pillars are disposed on back surfaces of the chips.

8. The composite circuit laminate according to claim 6, wherein a plurality of conductive pillars are disposed on the active surfaces of the chips.

9. The composite circuit laminate according to claim 1, further comprising:
a conductive pillar, penetrating the core composite layer and electrically connected to the first redistribution layer and the second redistribution layer.

10. The composite circuit laminate according to claim 9, wherein the conductive pillar comprises a first conductive pillar, a second conductive pillar, and a third conductive pillar, the first core sublayer surrounds the first conductive pillar, the second core sublayer surrounds the second conductive pillar, and the third core sublayer surrounds the third conductive pillar,
wherein an included angle is formed between a side surface of the first conductive pillar and a top surface of the first redistribution layer, and the included angle is less than 90 degrees.

11. A manufacturing method of a composite circuit laminate, comprising:
providing a carrier;
forming a first redistribution layer on the carrier;
forming a core composite layer on the first redistribution layer, wherein the core composite layer at least comprises a first core sublayer, a second core sublayer, and a third core sublayer;
forming a second redistribution layer on the core composite layer; and
removing the carrier,
wherein the first core sublayer, the second core sublayer, and the third core sublayer have unequal physical properties.

12. The manufacturing method of the composite circuit laminate according to claim 11, wherein the physical property comprises a coefficient of thermal expansion, a Young’s modulus, or a particle size of the core composite layer.

13. The manufacturing method of the composite circuit laminate according to claim 12, wherein the particle sizes of the first core sublayer, the second core sublayer, and the third core sublayer are less than 10 µm, between 10 µm and 50 µm, or greater than 50 µm.

14. The manufacturing method of the composite circuit laminate according to claim 11, further comprising:
forming a release layer between the carrier and the first redistribution layer.

15. The manufacturing method of the composite circuit laminate according to claim 14, further comprising:
forming an anti-warping layer between the carrier and the release layer.

16. The manufacturing method of the composite circuit laminate according to claim 11, further comprising:
forming a plurality of chips on the first redistribution layer, wherein the chips are selected from at least one of groups composed of a passive element, an active element, an optical element, and a bridge element.

17. The manufacturing method of the composite circuit laminate according to claim 11, further comprising:
forming a conductive pillar, wherein the conductive pillar penetrates the core composite layer or is surrounded by the core composite layer, and the conductive pillar is electrically connected to the first redistribution layer and the second redistribution layer.

18. The manufacturing method of the composite circuit laminate according to claim 17, wherein the step of forming the conductive pillar comprises:
forming a first conductive pillar on the first redistribution layer;
forming the first core sublayer surrounding the first conductive pillar;
forming a second conductive pillar on the first core sublayer, wherein the second conductive pillar is electrically connected to the first conductive pillar;
forming the second core sublayer surrounding the second conductive pillar;
forming a third conductive pillar on the second core sublayer; and
forming the third core sublayer surrounding the third conductive pillar, wherein the third conductive pillar is electrically connected to the second conductive pillar.

19. The manufacturing method of the composite circuit laminate according to claim 17, wherein the step of forming the conductive pillar comprises:
sequentially forming the first core sublayer, the second core sublayer, and the third core sublayer on the first redistribution layer;
forming a through hole penetrating the first core sublayer, the second core sublayer, and the third core sublayer; and
forming the conductive pillar in the through hole.

20. The manufacturing method of the composite circuit laminate according to claim 11, further comprising:
forming a third redistribution layer on the second redistribution layer; and
forming a plurality of electronic elements on the second redistribution layer.
